(19) United States
(12) Patent Application Publication
(10) Pub. No.: US 2009/0127544 A1
(43) Pub. Date: May 21, 2009

(54) Method for producing organic electronic devices on solvent-and/or temperature-sensitive plastic substrates

(76) Inventors: Mario Schrodner, Rudolstadt (DE); Karin Schultheis, Rudolstadt (DE); Hannes Schache, Rudolstadt (DE)

Correspondence Address: Horst M Kasper, 13 Forest Drive, Warren, NJ, 07059, US

(21) Appl. No.: 11/989,617

(22) PCT Filed: Jul. 26, 2006
(86) PCT No.: PCT/DE2006/001328

§ 371 Date: May 9, 2008

(30) Foreign Application Priority Data
Jul. 27, 2005 (DE) 10 2005 035 696.6

(51) Int. Cl. H01L 51/00; H01L 31/18; H01L 21/02; H01L 31/00; H01J 1/62

(52) U.S. Cl. 257/40; 438/99; 438/38; 438/82; 313/504; 136/259; 257/E21.002; 257/E51.018; 257/E31.118

(57) ABSTRACT

The invention relates to the production of organic field-effect transistors (OFETs), solar cells or light-emitting diodes (OLEDs) and circuits based thereon on the surface of solvent- and/or temperature-sensitive plastics, e.g. thermoplastic injection-moulded bodies. A protective layer, which comprises a polymer compound, such as polyacrylate, polyphenol, melamine resin or polyester resin, which is applied from an aqueous-alcoholic solution or without solvent to the substrate surface or one of the function-determining layers of the electronic semiconductor component in a low-temperature process at temperatures of less than 100° C. and dried, protects the substrate against undesirable action of solvents and may simultaneously serve as a planarization layer and/or as as electrical insulation layer.

The invention relates to the manufacture of organic field-effect transistors (OFETs), solar cells, or light emitting diodes (OLEDs) and circuits based thereon on the surface of solvent- and/or temperature-sensitive plastics, for example, thermo-plastic injection molded bodies. Furthermore, the invention relates to electronic components produced by said method.

### PRIOR ART

In the last years organic semiconductor components have obtained an increasing importance also due to economical aspects. So it is possible to easily produce and, hence, by low costs, for example, organic field-effect transistors (OFETs) by simple methods on various substrates such as silicon, glass, polyester foils (PET, PEN), or polyimide foils (C. J. Drury, C. M. J. Mutsaers, C. M. Hart, M. Matters and D. M. de Leeuw: Appl. Phys. Lett. 73 (1998), 108; F. Eder, H. Klauk M. Halik, U. Zschieschang, G. Schmid and C. Dehm, Appl. Phys. Lett. 84 (2004), 2673; J. Ficker, A. Ullmann, W. Fix, H. Rost and W. Clemens, Proc. SPIE 4466 (2001), 95; M. Schrödner, H.˜K. Roth, S. Sensfuss and K. Schultheis, e&i, 2003 (6), 2056; M. Halik, H. Klauk, U. Zschieschang, T. Kriem, G. Schmid and W. Radlik, Appl. Phys. Lett. 81 (2002), 289; H. Sirringhaus, T. Kawase, R. H. Friend, T. Shimoda, M. Inbasekaran, W. Wu and E. P. Woo: Science, 290 (2000), p. 2123). In general this is the better achieved the smoother the surface is and the more insensitive the material of the substrate is towards organic solvents. Since the manufacturing process of polymer electronic circuits very often requires tempering and drying steps, the maximal continuous service temperature of the substrate material is also of importance for the process control. Such requirements are substantially satisfied by, for example, polyethylene terephthalate (PET) and polyimide.

Furthermore it is known to manufacture organic electronic semiconductor components on foils which are coated with inorganic barrier layers for reducing any water diffusion and oxygen diffusion, respectively (U.S. Pat. No. 6,664,137). Such barrier layers, which ought to oppose any degradation of the field-effect transistors and of the circuits when operated, can also protect the substrate material against solvents, provided that these are applied sufficiently thick and without defects by a low-temperature process. They have, however, the disadvantage, compared to organic protective layers that they have to be precipitated by expensive and time-consuming vacuum processes.

WO 2004/091001 discloses a gate insulator for an organic semiconductor component, in particular for a field-effect transistor, which consists of a polysiloxane compound crosslinked at temperatures between 150° C. and 200° C. However, owing to the high crosslinking temperature, an application of the polysiloxane layer is not possible for protecting the ABS-substrates, polycarbonate substrates or the polystyrene substrates against the damaging effects of the solvents during the manufacturing procedure, apart from the fact that the polysiloxane layer is here used for electrical insulation.

In US2003/0224621 a method is given for producing organic semiconductor systems on different substrates such as, for example, textiles. This method also includes applying a protective layer upon the surface of a substrate beneath the semiconductor. But obviously it does not serve to protect the substrate against chemical actions by solvents. Moreover there are not given any information concerning the composition of the protective layer.

Due to economic reasons it is very often advantageous to produce the organic respectively the polymer-electronic circuit directly upon the object on which it will subsequently be used. For this task injection molded materials such as ABS-polymers, polycarbonate and polystyrene can be considered as particular suited materials. In contrast to silicon, glass, polyimide and other substrate materials, many of these injection molded materials, which very often are used as materials for electronic casings, compact discs (CDs), and DVDs, are sensitive to organic solvents. In addition, mostly their thermal load capacity is only low. Furthermore, the roughness of the surface of the employed injection molding tool also determines the surface roughness of the substrate so that the injection molded materials as basis materials for organic electronics are suited only strongly limited.

Due to the above mentioned reasons the use of these materials was heretofore problematic and there was not any suitable solution to overcome the difficulties mentioned hereinbefore.

### OBJECT OF THE INVENTION

It is an object of the present invention to provide a simple and low-priced method for producing organic field-effect transistors (OFETs), solar cells or light emitting diodes (OLEDs) on the surface of solvent- and temperature-sensitive plastics, which permits to manufacture such semiconductor components and circuits based thereon without any deterioration of the molded body such as an incipient dissolving of the surface or thermal deformation of the same.

The object of the present invention is realized by the features of the first Patent Claim. Further advantageous embodiments of the invention are object of a plurality of dependent claims. According to the present method an organic layer is applied, for example, partially or entirely, on the substrate surface of the injection molded body, said organic layer being insolvable by the subsequently employed solvents and the manufacture of the former does not require too high a temperature. Layer thicknesses between 1 μm and 5 μm are in general sufficient to protect the surface of this plastic body against the action of solvents. Simultaneously a smoothing of the mostly rough surface is carried out. Polymers capable of cross-linking such as acrylates, polyester- or epoxy resins have proven as particularly suited. To avoid any thermal stress on the plastic body, the cross-linkage should be carried out at low temperatures or photo-chemically. The applying of the protective layer can also be carried out by large-area coating processes, for example, by printing, doctoring or local dropping (micro-dosage method). Thereupon the setup of the organic components and the circuits of the same is then carried out.

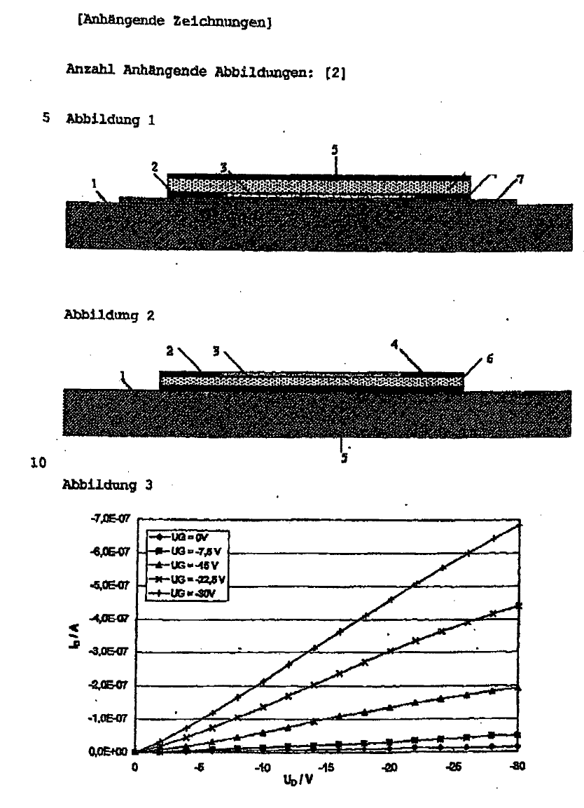

The invention will be explained hereinafter in more detail by virtue of two examples of field-effect transistors as well as of the FIGS. 1 to 4.

Organic or polymeric field-effect transistors (OFETs) in the sense of the present invention comprise at least the following substantial function-determining layers on a substrate:

An organic semiconductor layer between and above, respectively, under at least one source electrode and at least one drain electrode which consist out of a conducting organic or inorganic material, an organic insulating layer above or under the semi-conducting layer and an organic conducting layer. The respective integrated organic or polymeric electronic circuits consist of at least two organic or polymeric field-effect transistors.

FIG. 1 and FIG. 2 schematically show cross-sectional representations of field-effect transistors in accordance with the two examples of embodiments, whereby in FIG. 2 a version of the layer structure is selected in which the layers are arranged in reverse order compared to the structure shown in FIG. 1. Here a gate electrode 5 is generated from a conductive polymer dispersion directly upon the surface of a plastic body 1, whereby the conductive polymer dispersion does not attack the surface of the plastic. This can be, for example, an aqueous or an alcoholic dispersion of a soot composite. An (insulating) protective layer 6 is applied thereupon, which protects the plastic body and the injection molded body 1, respectively, against solvents and at the same time serves as an insulator between the gate electrode 5 and the source electrode and the drain electrode, respectively, 2, 4. Then an organic semiconductor layer 3 and the source electrode and the drain electrode, respectively, 2, 4 are applied thereupon. The deposit of the polymeric layers can be achieved by printing or by dropping (micro dosage process). The structuring of the electrodes can be obtained, for example, by laser operation, provided that it had not already been carried out with the printing operation.

### EXAMPLE 1

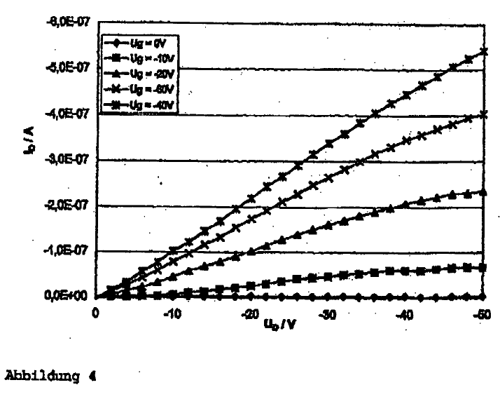

This example describes one realization of the invention according to FIG. 1. A layer of photo hardenable acrylates is applied as a protective layer 7 by doctoring to a plastic body 1 which is embodied as an ABS-plate of 1 mm thickness. The cross-linking is carried out by a high-power UV-lamp at an exposure time of up to 3 seconds. The layer thickness is about 5 μm. Thereupon a layer of a conductive soot-polymer composite is applied, also by doctoring. In this layer the source-drain electrodes 2, 4 are generated by selective abrasion with an excimer laser. Thereupon the polymer semiconductor 3 (poly-3-dodecylthiophen) is applied by spin coating (4000 r.p.m.) out of a 0.25%-chloroform or toluol-solution. Polyvinyl phenol is spin deposited at 2000 rotations per minute as an insulating layer 6 from a 20%-solution. The gate-electrodes 5 are generated by local depositing a colloidal graphite. FIG. 3 shows the output characteristic curve of a field-effect transistor produced in this manner.

### EXAMPLE 2

This example refers to the realization of the invention as shown in FIG. 2. A layer of the conductive polymer polyethylene dioxythiophen (Baytron) is applied by doctoring to an ABS-plate of 1 mm thickness as a plastic body 1. Said layer is structurized by selective laser abrasion with an excimer laser so that the gate electrodes 5 are obtained. Upon said layer and in order to generate the (insulation) protective layer 6, a layer of an alcoholic polyvinyl phenol solution containing a cross-linker is applied by spinning at 2000 r.p.m. Subsequently the polyvinyl phenol layer is tempered for 3 hours at 70° C. Over it, a thin gold layer (about 20 nm) is sputtered, out of which, in turn, the source-drain electrodes 2, 4 are generated by an excimer laser. Finally, the semiconductor layer 3 is applied by spinning up a 0.25% poly-3-hexylthiophen solution in toluol. The output characteristic of a field-effect transistor produced in such a way is shown in FIG. 4.

### LIST OF REFERENCE NUMERALS

1 plastic body
2 source electrode
3 semiconductor layer
4 drain electrode
5 gate electrode
6 insulation layer
7 heavily soluble protective layer

1. Method for producing organic field-effect transistors (OFETs), solar cells, or light emitting diodes (OLEDs) as electronic semiconductor components and electronic circuits based thereon, comprising a solvent- and/or temperature-sensitive plastic body as a substrate selected, for example, from an ABS-polymer, polycarbonate, or polystyrol, and further comprising on said substrate a layer system consisting of function determining layers being entirely or partially deposited, and a protective layer against chemical actions of solvents on the substrate, said solvents being selected from polymer compounds such as polyacrylate, polyphenol, melamine resin of polyester resin and which as an aqueous alcoholic solution or free of a solvent is applied to the substrate surface or to one of the function determining layers entirely or partially by a low temperature process at temperatures lower 100° C. and dried, and wherein the depositing of the electric functional layers of the components upon the plastic body and the structuring thereof is carried out by method steps known per se.

2. Method for producing organic field-effect transistors (OFETs), solar cells, or light emitting diodes (OLEDs) and electronic circuits based thereon as claimed in claim 1, characterized in that a thermal or a photochemical cross-linking of the polymer compounds forming the protective layer is carried out.

3. Method for producing organic field-effect transistors (OFETs), solar cells, or light emitting diodes (OLEDs) and electronic circuits based thereon as claimed in claim 2, characterized in that the thermal cross-linking of the polymer compound is carried out by temperatures lower than 100° C., preferably lower than 80° C.

4. Method for producing organic field-effect transistors (OFETs), solar cells, or light emitting diodes (OLEDs) and electronic circuits based thereon, as claimed in claim 1, characterized in that the polymeric protective layer is preferably applied to the plastic body by a printing process such as an offset printing, ink jet printing, pad printing, or screen printing, doctoring, or by a micro-dosage process, and in that the electric functional layers of the components are applied and structurized by the methods known per se.

5. Organic field-effect transistors (OFETs), solar cells, or light emitting diodes (OLEDs) and electronic circuits based thereon, with a solvent-sensitive and/or temperature sensitive plastic body as substrate and a layer system consisting of function determining layers arranged upon said substrate as well as a protective layer against chemical action of solvents towards said substrate, said protective layer consisting of an interlinked polymer compound such as polyacrylate, polyphenol, melamine resin or polyester resin characterized by the manufacturing method according to claim 1 to 4.

6. Organic field-effect transistors (OFETs), solar cells, or light emitting diodes (OLEDs) and electronic circuits based thereon as claimed in claim 5, characterized in that, as a plastic body, an injection molded body or a stamping formed body such as an electronic housing, a CD, a DVD or a chip card is employed.

7. Organic field-effect transistors (OFETs), solar cells, or light emitting diodes (OLEDs) and electronic circuits based thereon as claimed in claim 5, characterized in that the polymeric protective layer is designed as an electric insulation layer and/or as a planarizing layer.
